(19) United States
(12) Patent Application Publication
(10) Pub. No.: US 2004/0133825 A1
(43) Pub. Date: Jul. 8, 2004

(54) Path delay measuring circuitry

(75) Inventor: Takuya Kobayashi, Kanagawa (JP)

Correspondence Address: McDERMOTT, WILL & EMERY, 600 13th Street, N.W., Washington, DC, 20005-3096, US

(73) Assignee: MATSUSHITA ELECTRIC INDUSTRIAL CO., LTD

(21) Appl. No.: 10/698,532

(22) Filed: Nov. 3, 2003

(30) Foreign Application Priority Data
Nov. 8, 2002 (JP) P. 2002-325359

(51) Int. Cl. G01R 1/00; G11B 5/00; G06K 5/04; G11B 20/20

(52) U.S. Cl. 714/700; 324/158.1

(57) ABSTRACT

A path delay measuring circuitry includes a pattern creating circuit 105 for creating a test pattern to be supplied to a combination circuit 101, a comparison/decision circuit 106 for comparing an output from the combination circuit and an expected value, a clock creating circuit 301 for creating a clock with a variable clock interval while a capturing operation is carried out according to a clock mode value, and a timing signal creating circuit 107 for supplying an operation timing signal to each of the respective circuits. The clock generating circuit 301 includes a clock mode counter for producing a clock mode value which is updated whenever a decision for signal transition time is made.

### BACKGROUND OF THE INVENTION

This invention relates to a path delay measuring circuit which can measure automatically the path delay in a combination circuit in an LSI.

Generally, the measurement of the path delay in the combination circuit in an LSI is carried out using means of a scan test circuit. The mechanism is disclosed in the following non-patent reference.

Angela Krstic/Kwang-Ting (Tim) Cheng “DELAY FAULT TESTING FOR VLSI CIRCUITS” Kluwer Academic Publishers, United Kingdom, 1998, pp. 7-12.

In order to verify the performance of an LSI manufactured, as the case may be, the LSI is provided with means for measuring the above path delay. In this case, in a conventional path delay measuring circuit for its, measurement, clock supply, data input and the measurement of data output depend on an external arrangement.

More specifically, an input signal is externally supplied to the LSI, and an output signal is externally produced from the LSI. For example, it is common that the path delay using an LSI tester is evaluated in the following manner. A test pattern is supplied from the LSI tester, and the expected value corresponding to the test pattern and the output signal are compared with each other by the LSI tester so that the output signal is decided.

The above conventional technique, however, presents problems that the test pattern to be used for decision in the LSI tester is complicate and the operation on the LSI tester and test program in the LSI tester are also complicate. Further, where the clock supplied from the LSI tester is directly sent to a path delay measuring circuit, a problem also occurs that the precision of delay measurement depends on the capability of creating a waveform by the LSI tester.

### SUMMARY OF THE INVENTION

This invention has been accomplished in order to solve the above problems in the conventional technique.

An object of this invention is to provide a path delay measuring circuit which can measure automatically the path delay in a combination circuit without using an LSI tester.

In order to solve this problem, according to first aspect of the invention, a path delay measuring circuitry includes a first and a second flip-flop which are connected to an input of a combination circuit whose path delay is to be measured and constitute a scan-chain and a third flip-flop which is connected to an output from the combination circuit to constitute the scan chain, and in which after a test pattern is set for the first and the second flip-flop by a shifting operation of the scan chain, the output from the combination circuit is taken into the third flip-flop by a capturing operation and an output from the third flip-flop is compared with an expected value so that the time taken for the capturing operation is made variable, thereby judging a signal transition time of the combination circuit, further comprising a pattern creating circuit for creating a test pattern to be set for the first and the second flip-flop, a comparison/decision circuit for comparing the output from the third flip-flop and the expected value, and a timing signal creating circuit for supplying an operation timing signal to each of the first, second and third flop-flops, the pattern creating circuit and the comparison/decision circuit, wherein a clock interval of the time taken for the capturing operation is made variable, thereby judging a signal transition time of the combination circuit.

In accordance with the above configuration, to supply a value created by the pattern creating circuit to the combination circuit and to decide the output from the combination circuit can be performed automatically using an operation timing signal created by the timing signal creating circuit. This makes unnecessary a complicate operation by an LSI tester and a complicate test program.

According to second aspect of the invention, the path delay measuring circuitry further comprises a multiplying circuit for creating a high speed clock on the basis of a clock externally supplied, a clock mode counter for outputting a clock mode value which is updated whenever the signal transition time is decided, and a clock creating circuit for creating another clock to be supplied to the path delay measuring circuit on the basis of the high speed clock and the clock mode value, in that the clock created by the clock creating circuit is made variable in its clock interval of the time to be taken for the capturing operation according to the clock mode value.

In accordance with the above configuration, since the clock interval taken for the capturing operation of the clock automatically created is updated in correlation to updating of the clock mode value, the signal transition time in the combination circuit can be known from the clock mode value, and the path delay can be easily measured automatically.

Preferably, a plurality of flip-flops may be provided which are identical to the first and second flip-flops.

Preferably, a plurality of flip-flops may be provided which are identical to the third flip-flop.

In accordance with the configuration of the path delay measuring circuitry, since a plurality of measuring points and control points of the combination circuit whose path delay is to be measured are prepared and their inputs and outputs can be controlled, thereby permitting various measurements of the path delay to be measured.

According to the another aspect of the invention, a semiconductor device incorporates a plurality of path delay measuring circuits each described above. In accordance with the above configuration, the path delay at various points in a semiconductor chip or wafer can be measured to obtain information on changes in the path delay on the semiconductor chip or wafer.

### BRIEF DESCRIPTION OF THE DRAWINGS

FIG. 1 is a block diagram showing the arrangement of a path delay measuring circuit according to the first embodiment of this invention;

FIG. 2 is a timing chart for explaining the operation of the path delay measuring circuit according to the first embodiment;

FIG. 3 is a block diagram showing the arrangement of a path delay measuring circuit according to the second embodiment of this invention;

FIG. 4 is a block diagram showing an exemplary arrangement of the clock creating circuit in this invention;

FIG. 5 is a timing chart for explaining the operation of the path delay measuring circuit according to the second embodiment;

FIG. 6 is a block diagram showing the arrangement of a path delay measuring circuit according to the second embodiment of this invention; and

FIG. 7 is a view showing an exemplary semiconductor device including a plurality of path delay measuring circuits according to this invention.

### DETAILED DESCRIPTION OF THE PREFERRED EMBODIMENTS

Now referring to the drawings, an explanation will be given of various embodiments of this invention.

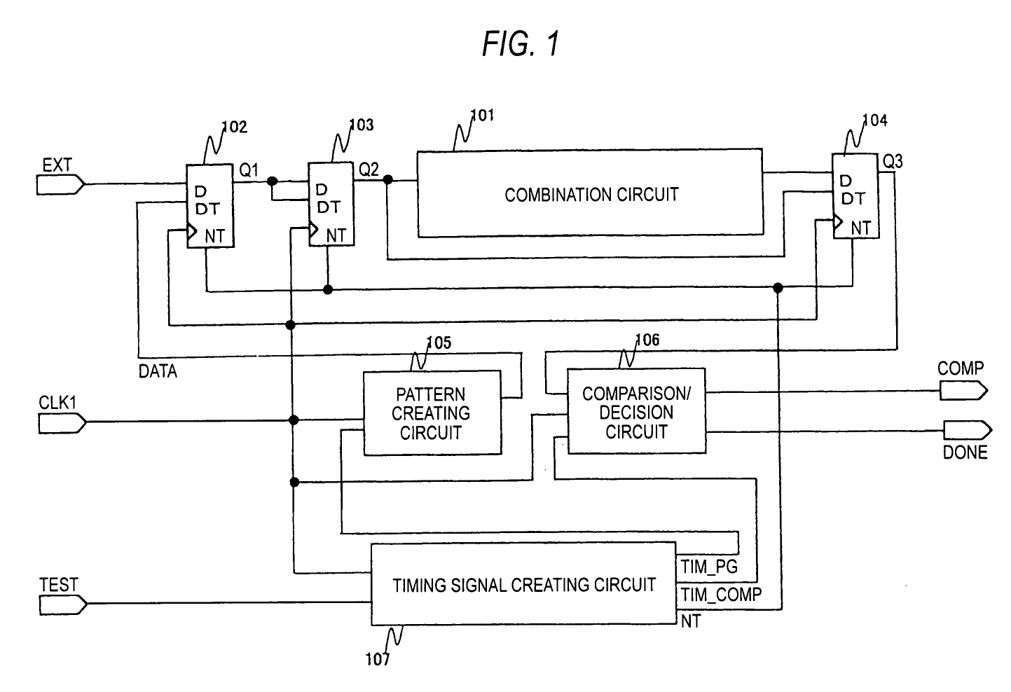

FIG. 1 is a block diagram showing the arrangement of a path delay measuring circuit according to the first embodiment of this invention. In FIG. 1, reference numeral 101 denotes a combination circuit in which the path delay is to be measured; 102, 103 and 104 denote a flip-flop, respectively; 105 denotes a pattern creating circuit; 106 denotes a comparison/decision circuit; and 107 denotes a timing signal creating circuit.

The first flip-flop 102 sets a signal value to be supplied to the combination circuit 101. The second flip-flop 103 supplies the signal received from the first flip-flop 102 to the combination circuit 101. The third flip-flop 104 takes in the output from the combination circuit 101. The timing signal creating circuit 107 includes a counter circuit which performs a counting operation with a clock CLK1. On the basis of the counted values, a scan mode test mode signal NT, a pattern creating timing signal TIM_PG and a comparison decision timing signal TIM_COMP are created.

On the basis of the pattern creating timing signal TIM_PG, the pattern creating circuit 105 sets a test pattern for the first flip-flop 102 and the second flip-flop 103. On the basis of the comparison decision timing signal TIM_COMP, the comparison decision circuit 106 compares the transition in the output from the third flip-flop 104 with the expected value corresponding to the test pattern to produce a comparison decision signal COMP and a test completing signal DONE.

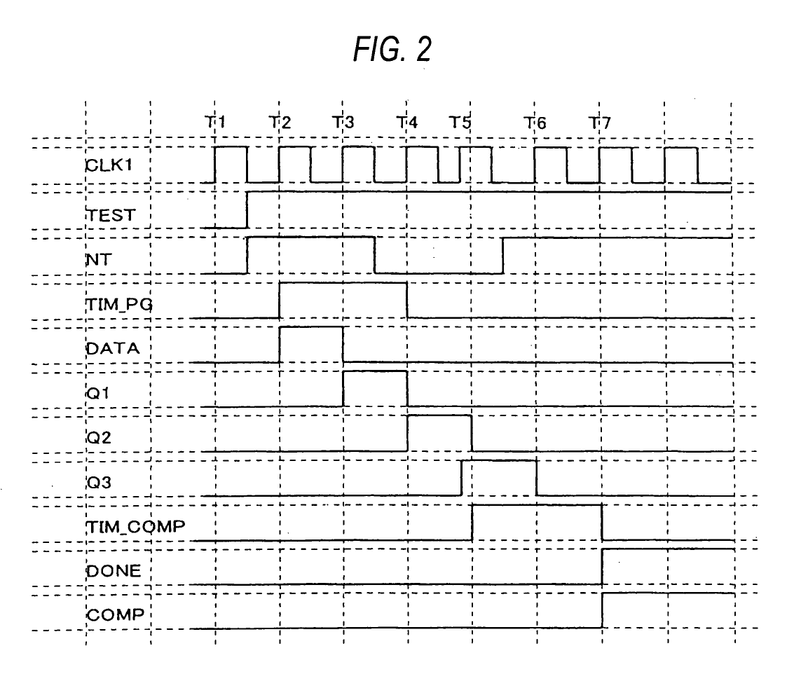

FIG. 2 is a timing chart for explaining the operation of the path delay measuring circuit shown in FIG. 1. In FIG. 2, at timing T2, a signal TEST for performing a path delay test becomes “H” (enable). Simultaneously, the scan test mode signals NT's for the first to third flip-flops 102, 103 and 104 become “H” so that each flip-flop takes in the data from its own scan test mode input DT.

At timings T2 and T3, the pattern timing signal TIM_PG becomes “enable”, the test pattern DATA to be supplied to the combination circuit 101 propagates in the order of the first flip-flop 102 and the second flip-flop 103.

At timings T4 and T5, the scan test mode signal NT becomes “L”. In this case, each flip-flopper forms an ordinary operation so that the output signals from the second flip-flop 103 and the first flip-flop 104 are successively supplied to the combination circuit 101. At this time, the third flip-flop 104 takes in the output value at timing T5.

At timing T6, the scan test mode signal NT becomes “H” to perform the scan operation so that the output signal from the third flip-flop 103 propagates to the comparison/decision circuit 106. In the comparison/decision circuit 106, the expected value corresponding to the test pattern and the propagated signal are compared with each other so that the comparison result is produced as a comparison/decision signal COMP and a test completing signal DONE indicative of the completion of one test cycle.

In the path delay measuring circuit which operates in the manner described above, the time from timing T4 to timing T5 in the timings of clock CLK1 which is externally supplied can be varied optionally and at each time of variation, the data acquired from the third flip-flop 104 and the expected value are compared and decided by the comparison/decision circuit 106. Thus, the time taken for the signal transition in the combination circuit can be automatically measured.

Incidentally, this embodiment has been explained for the case where an MUX type scan flip-flop was used as the scan flip-flop. However, it is needless to say that any other type of scan flip-flop can be adopted.

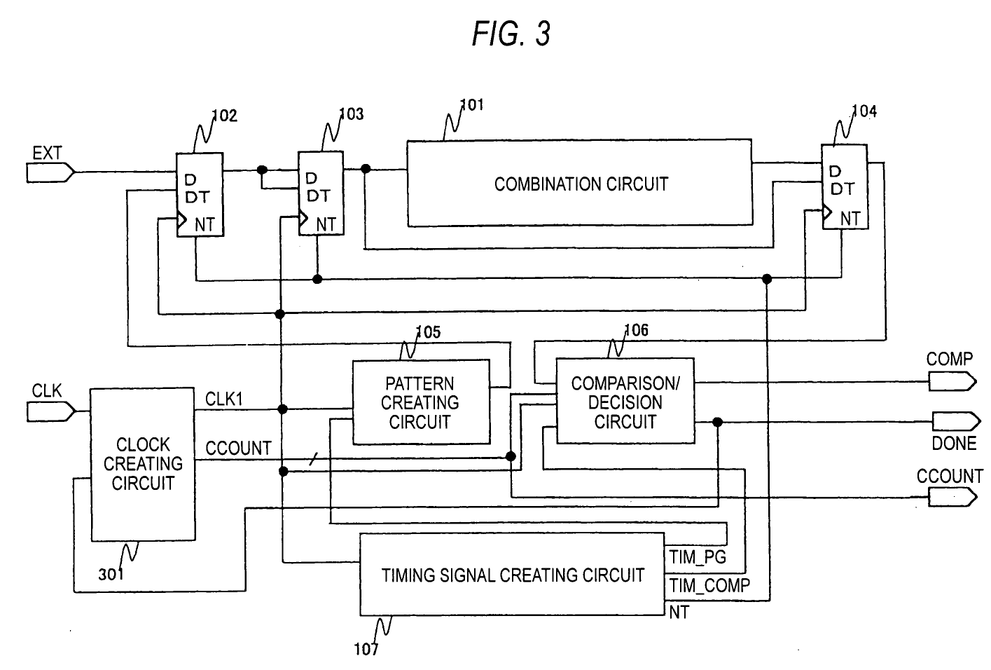

FIG. 3 is a block diagram showing the arrangement of a path delay measuring circuit according to the second embodiment of this invention. In FIG. 3, like reference numerals refer to like parts or elements in FIG. 1. In FIG. 3, reference numeral 301 denotes a clock creating circuit for creating a clock CLK1 used to the path delay on the basis of the clock input CLK externally supplied and for producing a signal CCOUNT for identifying the status of the clock CLK1.

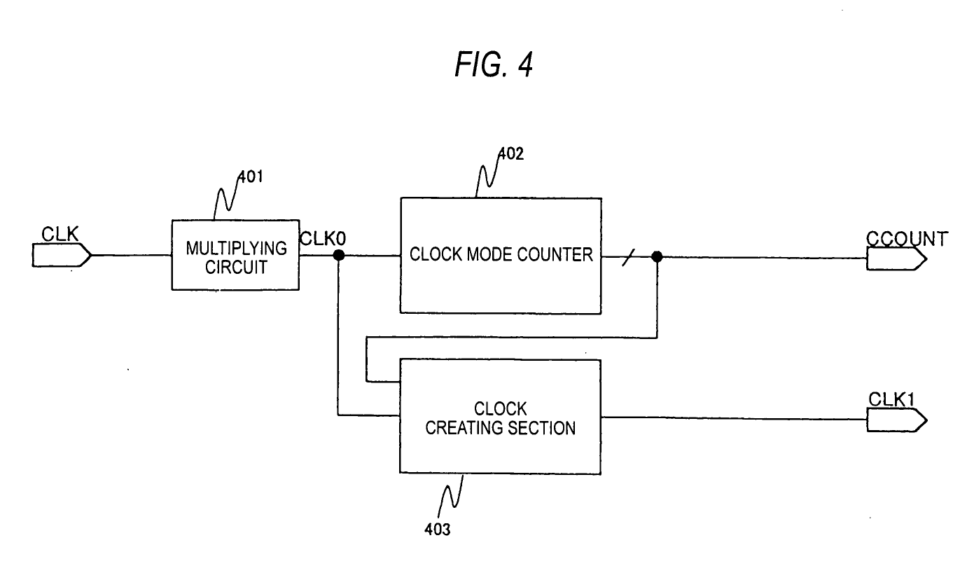

FIG. 4 is a block diagram showing an exemplary arrangement of the clock creating circuit 301. In FIG. 4, reference numeral 401 denotes a multiplying circuit for creating a high speed clock CLK0 on the basis of the clock input CLK; 402 denotes a clock mode counter for creating the identifying signal CCOUNT; and 403 denotes a clock creating section for creating a clock CLK1.

The clock mode counter 402 creates the identifying signal CCOUNT on the basis of the clock CLK0 multiplied to the high speed by the multiplying circuit 401. The clock creating section 403 creates the clock CLK1 on the basis of the high speed clock CLK0 created by the multiplying circuit 401 and the identifying signal CCOUNT produced from the clock mode counter 402.

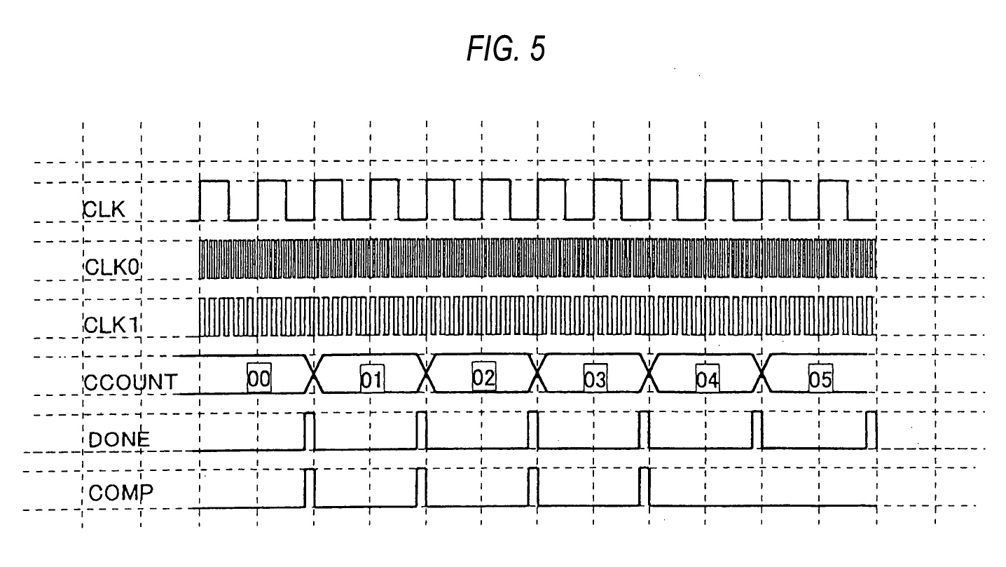

FIG. 5 is a timing chart for explaining the operation of the path delay measuring circuit shown in FIGS. 3 and 4. As seen from FIG. 5, a low speed external clock CLK is multiplied into a high speed clock CLK0 by the multiplying circuit 401. On the basis of the clock CLK0, an identifying signal CCOUNT is created by the clock mode counter 402. Further, on the basis of the identifying signal CCOUNT and clock 0, a clock CLK1 is created by the clock creating section 403.

In this case, the clock CLK1 thus created is caused to have a time difference for the clock interval when the capturing operation is done from the timing T4 to T5 in FIG. 2 according to the value of the identifying signal CCOUNT. Specifically, when the identifying CCOUNT is 00, a sufficiently large time difference is given for the designed value of the path delay in the combination circuit 101, and the time difference is gradually decrease date very increment of the identifying signal CCOUNT.

In this way, since the value of the identifying CCOUNT is caused to correspond uniquely to the time difference in the clock CLK1, by monitoring the test completion signal DONE and the comparison/decision signal in the value of each identifying signal CCOUNT, the limited value of the path delay in the combination circuit 101 can be measured.

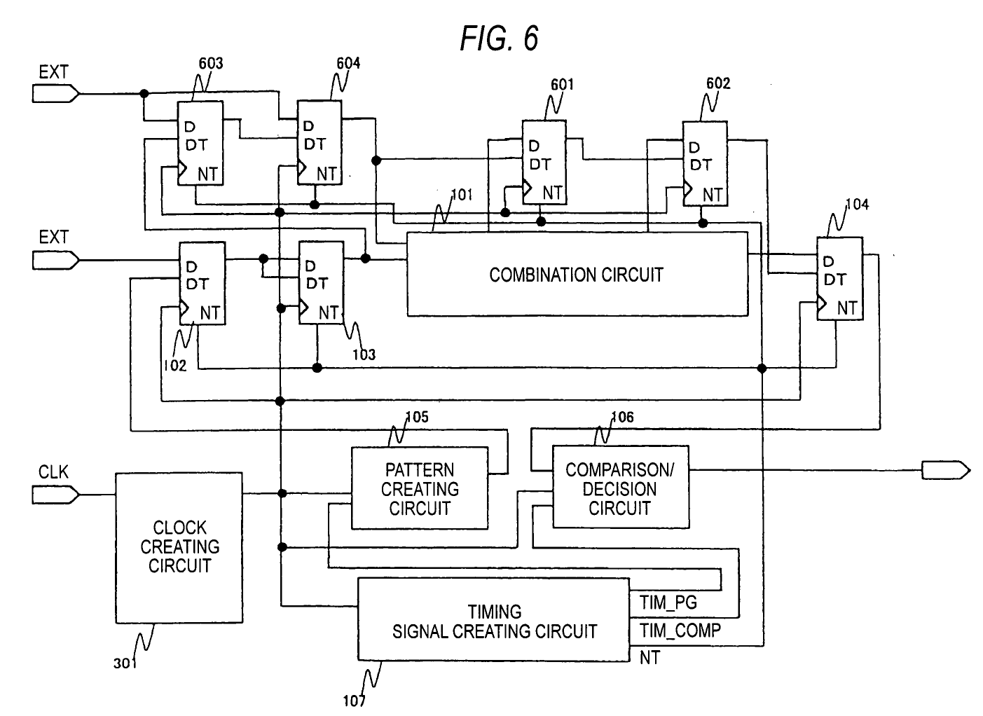

FIG. 6 is a block diagram showing the arrangement of a path delay measuring circuit according to the third embodiment of this invention. In FIG. 6, like reference numerals refer to like parts or elements in FIGS. 1 and 3 In FIG. 6, reference numerals 601, 602, 603, and 604 denote flip-flops newly added.

The sixth flip-flop 603, like the first flip-flop 102, serves to set a signal value to be inputted to the combination circuit 101, and the seventh flip-flop 604, like the second flip-flop 103, serves to supply the signal received from the sixth flip-flop 603 to the combination circuit 101. The fourth flip-flop 601 and the fifth flip-flop 602, like the third flip flop 104, takes in the output from the combination circuit 101 in order to monitor the internal signal transition.

In this way, a plurality of sets of flip-flops each inclusive of the flip-flop for controlling the input signal to the combination circuit and the flip-flop for monitoring the output signal are provided, and each flip-flop is controlled by the timing signal creating circuit 107. Such a configuration permits the delay for a variety of passes in the combination circuit 101 to be measured.

It is needless to say that the number of flip-flops for monitoring the signal transition within the combination circuit 101 and the number of flip-flops for supplying the signal to the combination circuit should not be limited to the number of flip-flops used in this embodiment.

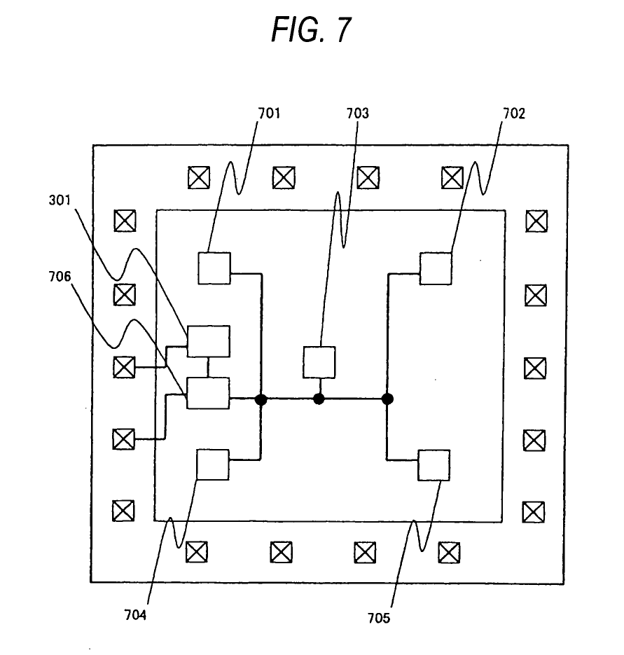

FIG. 7 is a view showing an exemplary semiconductor device including a plurality of path delay measuring circuits according to this invention. In FIG. 7, reference numerals 701-705 denote a path delay measuring circuit according to this invention, respectively; and reference numeral 706 denotes a control circuit for controlling the path delay measuring circuits 701-705. In this case the clock generating circuit 301 may be a single circuit which is common to the respective path delay measuring circuits 701-705.

For example, if the plurality of path delay measuring circuits included in the LSI are made in substantially the same circuit and layout, the variation in the path delay attributable to the physical arrangement within the LSI can be easily measured.

[Effect of the Invention]

As understood from the description hitherto made, in accordance with this invention, the path delay measuring device for the combination circuit using the mechanism of the scan test circuit includes a timing signal generating circuit, a pattern generating circuit, a comparison/decision circuit and a clock generating circuit. This makes unnecessary the complicate operation and test program for an LSI tester, thereby permitting the path delay measurement for the combination circuit to be easily carried out. Further, the provision of these path delay measuring circuits within the LSI permits the variation in the path delay within the LSI to be easily measured.

What is claimed is:

1. A path delay measuring circuitry for judging a signal transition time of a combination circuit whose path delay is to be measured, comprising:
first and a second flip-flop which are connected to an input of the combination circuit and constitute a scan-chain;
a third flip-flop which is connected to an output from said combination circuit to constitute the scan chain;
a pattern creating circuit for creating a test pattern to be set for said first and said second flip-flop;
a comparison/decision circuit for comparing the output from said third flip-flop and the expected value; and
a timing signal creating circuit for supplying an operation timing signal to each of the first, second and third flop-flops, said pattern creating circuit and said comparison/decision circuit,
wherein after a test pattern is set for said first and said second flip-flop by a shifting operation of the scan chain, the output from said combination circuit is taken into said third flip-flop by a capturing operation and an output from said third flip-flop is compared with an expected value, and a clock interval of the time taken for the capturing operation is made variable.

2. A path delay measuring circuitry according to claim 1, further comprising:
a multiplying circuit for creating a high speed clock on the basis of a clock externally supplied;
a clock mode counter for outputting a clock mode value which is updated whenever said signal transition time is decided; and
a clock creating circuit for creating another clock to be supplied to said path delay measuring circuit on the basis of said high speed clock and said clock mode value,
wherein the clock created by said clock creating circuit is made variable in its clock interval of the time to be taken for said capturing operation according to said clock mode value.

3. A path delay measuring circuitry according to claim 1, wherein a plurality of flip-flops are provided which are identical to said first and second flip-flops.

4. A path delay measuring circuitry according to claim 2, wherein a plurality of flip-flops are provided which are identical to said first and second flip-flops.

5. A path delay measuring circuitry according to claim 1, wherein a plurality of flip-flops are provided which are identical to said third flip-flop.

6. A path delay measuring circuitry according claim 2, wherein a plurality of flip-flops are provided which are identical to said third flip-flop.

7. A semiconductor device comprising a plurality of path delay measuring circuits, each path delay measuring circuitry judging a signal transition time of a combination circuit whose path delay is to be measured, said path delay measuring circuitry comprising:
first and a second flip-flop which are connected to an input of the combination circuit and constitute a scan-chain;
a third flip-flop which is connected to an output from said combination circuit to constitute the scan chain;
a pattern creating circuit for creating a test pattern to be set for said first and said second flip-flop;
a comparison/decision circuit for comparing the output from said third flip-flop and the expected value; and
a timing signal creating circuit for supplying an operation timing signal to each of the first, second and third flop-flops, said pattern creating circuit and said comparison/decision circuit,
wherein after a test pattern is set for said first and said second flip-flop by a shifting operation of the scan chain, the output from said combination circuit is taken into said third flip-flop by a capturing operation and an output from said third flip-flop is compared with an expected value so that a clock interval of the time taken for the capturing operation is made variable.

8. A semiconductor device comprising as claimed in claim 7, wherein said path delay measuring circuitry further comprises:
a multiplying circuit for creating a high speed clock on the basis of a clock externally supplied;
a clock mode counter for outputting a clock mode value which is updated whenever said signal transition time is decided; and
a clock creating circuit for creating another clock to be supplied to said path delay measuring circuit on the basis of said high speed clock and said clock mode value,
wherein the clock created by said clock creating circuit is made variable in its clock interval of the time to be taken for said capturing operation according to said clock mode value.
